(19) United States
(12) Patent Application Publication
(10) Pub. No.: US 2007/0235732 A1
(43) Pub. Date: Oct. 11, 2007

(54) Electrical arrangement comprising a wire connection arrangement and method for the production of such an electrical arrangement

(76) Inventors: Silvia Gohlke, Regensburg (DE); Sieglinde Kraus, Regensburg (DE); Hans Rappl, Nittendorf (DE); Gunther Rauscher, Kunzing (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/675,962

(22) Filed: Feb. 16, 2007

(30) Foreign Application Priority Data
Feb. 16, 2006 (DE) 10 2006 007 306.1
Feb. 1, 2006 (DE) 10 2006 004 602.1

(51) Int. Cl. H01L 29/06

(52) U.S. Cl. 257/41

(57) ABSTRACT

An electrical arrangement has a first electrically conductive contact point (10) and a second electrically conductive contact point (20), the first and the second contact point being arranged at a distance (x) from one another and being electrically connected to one another via a wire connection arrangement (30), the wire connection arrangement (30) being formed by at least two wire connections (31-1, 31-2, . . . , 31-n-1, 31-n) which have respectively a first end (32-1, 32-1, 32-n-1, 32-n) and a second end (33-1, 33-2, . . . , 33-n-1, 33-3), and the first end of a wire connection (30-2, . . . , 30-n) and the second end of a preceding wire connection (30-1, . . . , 30-n-1) being in direct contact with one another.

### CROSS-REFERENCE TO RELATED APPLICATIONS

This application claims priority to German application number 10 2006 007 306.1 filed Feb. 16, 2006, the contents of which are hereby incorporated by reference in its entirety.

### TECHNICAL FIELD

The invention relates to an electrical arrangement comprising a first electrically conductive contact point and a second electrically conductive contact point, the first and the second contact point being arranged at a distance from one another, and being electrically conductively connected to one another via a wire connection arrangement. The invention also relates to a method for the production of such an electrical arrangement.

### BACKGROUND

The production of electrically conductive connections between two contact points using a so-called bonding wire is widespread in microelectronics. Bonding wires are used, for example, for electrically bonding a semiconductor chip to a substrate. The reliability of a wire connection, particularly in the bridging of long distances, can be low, particularly if the electrical arrangement is exposed to environmental influences such as e.g. vibrations. To reduce susceptibility to faults, bonding wires of a thicker diameter are therefore frequently used. Besides higher material costs, the electrically conductive contact points for bonding with such a bonding wire have to be fashioned so as to be larger so that the electrical arrangement has a greater space requirement overall. However, such an approach is not possible in the case of the electrical bonding of semiconductor components, in particular.

### SUMMARY

The object of the present invention is therefore to specify an electrical arrangement by means of which the disadvantages indicated above can be avoided.

A further object of the present invention is to specify a method for the production of such an electrical arrangement.

According to an embodiment, an electrical arrangement may have a first electrically conductive contact point and a second electrically conductive contact point, wherein the first and the second contact point are arranged at a distance from one another, and are electrically connected to one another via a wire connection arrangement, wherein the wire connection arrangement is formed by at least two wire connections, which respectively have a first end and a second end, and the first end of one wire connection and the second end of a preceding wire connection are in direct contact with one another. According to another embodiment, a method for the production of an electrical arrangement, may comprise the steps of a) providing a substrate arrangement comprising a first contact point, a second contact point and at least one further contact point; b) producing a first connection to the first contact point with a wire bonding device, wherein the first end of a first wire connection is connected to the first contact point, c) producing a second connection to the further contact point with the wire bonding device, wherein the second end of the first wire connection is connected to the further contact point, wherein the second end connected to the further contact point facing away from the further contact point; d) producing a third connection to the second end of the first wire connection with the wire bonding device, wherein the first end of a second wire connection is connected to the wedge face of the first wire connection, e) producing a fourth connection to the second contact point with the wire bonding device, wherein the second end of the second wire connection is connected to the second contact point.

### BRIEF DESCRIPTION OF THE DRAWINGS

Further advantages and features of the invention will be explained in detail below with reference to the drawings, in which:

FIG. 1 shows a section through a first exemplary embodiment of an electrical arrangement which is formed by a semiconductor chip placed on a carrier,

FIG. 2 shows a plan view of the electrical arrangement shown in FIG. 1,

FIG. 3 shows a schematic representation of a multilayer piezostack known from the prior art, from which multilayer piezostack the electrical interconnection can be seen,

FIG. 4 shows the bonding method known in the prior art in respect of the multilayer piezostack shown in FIG. 3, and

FIG. 5 shows a schematic cross-sectional representation of the electrical bonding of a multilayer piezostack according to an embodiment.

### DETAILED DESCRIPTION

In an electrical arrangement according to an embodiment, comprising a first, electrically conductive, contact point and a second, electrically conductive, contact point, the first and the second contact points being arranged at a distance from one another and being connected to one another in an electrically conductive manner via a wire connection arrangement, the wire connection arrangement being formed by at least two wire connections which respectively have a first end and a second end, and the first end of a wire connection and the second end of a preceding wire connection being in direct contact with one another.

In this way, the wire connection arrangement can be fashioned in the form of a chain of multiple individual wire connections, each having an optimized length, it being possible in principle for a random number of individual wire connections to be provided. The use of a wire connection arrangement of this type avoids providing a single wire connection between two contact points which are far apart. In this way, an electrical arrangement can be provided which has greater reliability and which, in particular, can be used in applications which are exposed to powerful environmental influences such as e.g. vibrations. Also, no wire connections of an unusual diameter have to be used in order to overcome greater distances between the first and the second contact point. This on the one hand simplifies production since wire connections having normally used cross-sections can be used. In addition, the first and the second contact points do not have any greater space requirement than conventional arrangements.

A particularly good level of reliability is obtained if the first end of the wire connection is connected to the second end of the adjacent preceding wire connection in a materially bonded manner. To produce a materially bonded connection, any conventional known connecting method can in principle be used. Production of the wire connection arrangement, which moreover has a low space requirement, is then possible in a particularly simple manner if according to a further embodiment the first end is superimposed on the second end. It is particularly useful here if the first end represents a nailhead and the second end a wedge face, in particular a wedge, the first end being superimposed on the second end by means of a thermocompression bonding method. The chain bonding performed enables the production, without loss of space, of a randomly long, electrically conductive bond connection between the first and the second contact point. The underlying approach here is to place the respectively following bond connection, which is known to the person skilled in the art by the term bond loop, on to the end of the preceding wire connection (bond loop).

A particularly stable arrangement emerges where the first and the second contact point are fashioned on a substrate arrangement and form electrical connection contacts of the arrangement, and the first or the second end of wire connections that are connected to one another are arranged on a further contact point of the substrate arrangement and form an intermediate contact. The chain bonding between the first and the second contact point is thus implemented via intermediate contacts representing support points. The distances between the first or second contact point and a further contact point or between two further contact points can be selected with a view to maximum reliability of the bond connection. The advantage of this procedure is in particular that the further contact points on the substrate arrangement do not, for example, need to be bonded to an electrical conductor arrangement, which enables great flexibility in the establishment of the layout, e.g. on the substrate arrangement. In particular, it is possible by this means to arrange the first and the second contact points in an optimized manner with regard to a conductor track layout, without having to take into account the distance between the first and second contact points.

According to a further embodiment, at least one substrate section of the substrate arrangement is electrically insulating in the area of the intermediate contact(s). The further contact point arranged in the area of the intermediate contact thus has merely the function of producing a mechanical connection of the wire connections that are in electrical contact with one another to the substrate arrangement.

According to a further embodiment, at least one substrate section of the substrate arrangement in the area of the intermediate contact(s) is electrically conductive, the further contact being conductively connected to the substrate arrangement. Thus not only the bridging of large distances between a first and a second contact point is enabled, but also alternative interconnection techniques which are normally produced using, for example, soldered and wire connections.

According to a further embodiment, the substrate arrangement is formed by a semiconductor element which is arranged on a carrier, the first connection contact being fashioned on the semiconductor element and the second connection contact being fashioned on the carrier.

According to a different design, the substrate arrangement is formed by a number of elements, in particular solid-state actuators, stacked on top of one another, the elements stacked on top of one another being connected in parallel via two wire connection chains which are formed respectively from a number of wire connections that are in direct contact with one another. In the case of the electrical arrangement described here, the principle of the wire chain connection is used for bonding e.g. a multilayer piezostack.

It is particularly advantageous if the wire connections and/or the contact points and/or the further contact point(s) have at least one surface made of gold. By this means, an optimal mechanical connection can be produced between the linked partners, so that a maximal mechanical load-bearing capacity of the resulting electrical arrangement is achieved.

As explained hereinbefore, the same advantages are associated with the method according to an embodiment for the production of an electrical arrangement which is configured as described above.

An method according to an embodiment for the production of an arrangement of this type may comprise the following steps:
a) provision of a substrate arrangement comprising a first contact point, a second contact point and at least one further contact point;
b) production of a connection, in particular a materially bonded connection, to the first contact point with a wire-bonding device, the first end of a first wire connection being connected, in particular in a materially bonded manner, to the first contact point;
c) production of a connection, in particular a materially bonded connection, to the further contact point with the wire-bonding device, the second end of the first wire connection being connected, in particular in a materially bonded manner, to the further contact point, the second end connected to the further contact point having a wedge face facing away from the further contact point;
d) production of a connection, in particular a materially bonded connection, to the second end of the first wire connection with the wire-bonding device, the first end of a second wire connection being connected, in particular in a materially bonded manner, to the wedge face of the first wire connection;
e) production of a connection, in particular a materially bonded connection, to the second contact point with the wire-bonding device, the second end of the second wire connection being connected, in particular in a materially bonded manner, to the second contact point.

According to one embodiment, it is provided that, in order to produce a chain connection comprising more than two wire connections, steps c) and d) be repeated.

The underlying principle within the framework of the method according to an embodiment is to place the respectively following first end of the wire connection (bond loop) on to the second end of the preceding wire connection (bond loop). On account of the identical materials of the two wire connections and their materially bonded connection, an optimal mechanical contact is produced which will also withstand powerful environmental influences. In addition, compared with the conventional bonding method, no additional space is needed since the wedge face provided by the second end of the preceding wire connection serves as a bonding surface for the first end of the subsequent wire connection.

It is furthermore preferable if the step of connecting one of the following contact partners is performed by means of microwelding:
the first end of the wire connection to the first contact point or to the second end of the preceding wire connection,
the second end of the wire connection to the further contact point or to the second contact point.

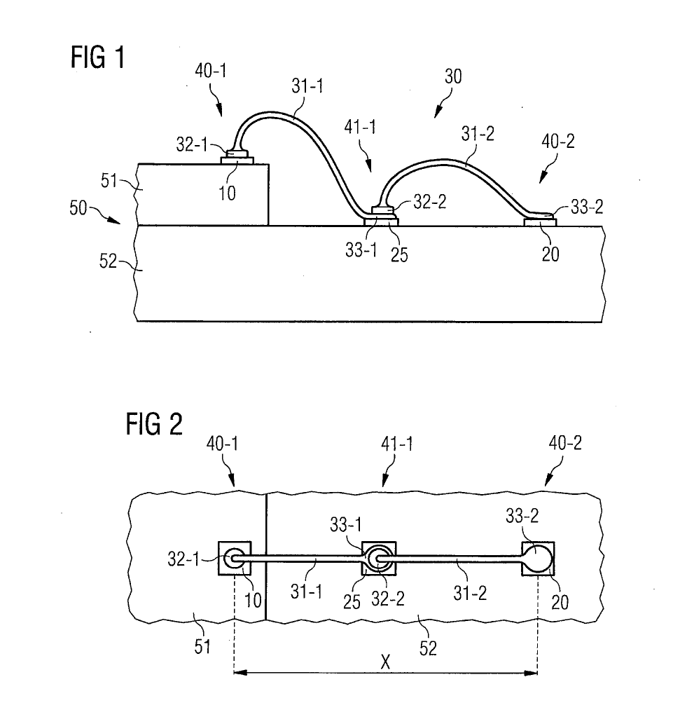

A first exemplary embodiment of an electrical arrangement is described below with reference to FIGS. 1 and 2. A substrate arrangement 50 comprises a carrier 52 consisting of an insulating material, on which carrier a semiconductor element 51 is placed, e.g. by means of soldering, bonding or in another random manner. The semiconductor element 51 comprises on its main surface facing away from the carrier 52 a first contact point 10. The first contact point 10 may consist e.g. in a known manner of a metallization. A second contact point 20 is placed on the carrier 52. The contact point 20 may for example be part of a conductor track arrangement not shown in detail in the drawings. An electrical connection between the first and the second contact point 10, 20 is produced by means of a wire connection arrangement 30.

The wire connection arrangement 30 comprises in the present exemplary embodiment two wire connections 31-1 and 31-2, which are also called bonding wires. Preferably, but not necessarily, the wire connections 31-1, 31-2 and the contact points 10, 20 and a further contact point 25, which in the example is also placed on the carrier 52 and arranged between the first and second contact point 10,20, are made of gold or a gold alloy.

The wire connection 31-1 has a first end 32-1 and a second end 33-1. In a corresponding manner, the second wire connection 31-2 comprises a first end 32-2 and a second end 33-2. The wire connections 31-1 and 31-2 are placed using a conventional thermocompression bonding method. Accordingly, the first ends of the wire connections are also called nailheads and the second ends of the wire connections wedge faces or wedges.

The first end 32-1 of the first wire connection 31-1 is pressed on to the area to be bonded, the first contact point 10. The electrical connection is produced by microwelding the wire connection, e.g. by means of a short ultrasonic pulse, to the first contact point 10. A capillary or needle is then moved to the further contact point 25, bonding wire being guided through the needle tip or capillary. The wire is pressed on to the further contact point 25 and connected to said contact point, e.g. by means of an ultrasonic pulse, which this time also separates the wire. This produces the wedge face on the second end 33-1 of the first wire connection, which wedge face has approximately the dimensions of the further contact point 25. The wedge face on the second end 33-1 of the first wire connection 31-1 forms the contact surface for the second wire connection 31-2. Correspondingly, the first end 32-2 of the second wire connection 31-2 is pressed on to the wedge face on the second end of the first wire connection and microwelded to said wedge face, e.g. by a short ultrasonic pulse. The further connection of the second end 33-2 of the second wire connection 31-2 is produced as described previously.

Through repetition of the procedure described, randomly long connections can be produced between the first and the second contact point 10, 20. The procedure according to an embodiment is suitable in particular where the distance x which exists between the first and second contact point is of such a magnitude that a bond connection with a single wire connection is either not possible or there is the risk of damage to the wire connection and in particular to the connections with the contact points due to external influences.

The arrangement of the first end of a wire connection on the second end of the previous wire connection gives rise to a lower spatial requirement than in the case of a conventional connecting method in which the two ends of the first and the second wire connection are respectively placed on their own contact points and, for bridging the distance between first and second contact point 10, 20, only one, then a thicker, wire connection is used. Reliability compared with a “long” wire connection is increased by standard-wire connections. A further advantage is that connections can be produced on different surfaces, as a result of which cost-effective carriers can also be used. In addition, the degree of freedom when drawing up the conductor track geometry, in particular on the carrier 52, is increased, since the distance between the first and the second contact points 20, which in the present exemplary embodiment form connection contacts 40-1 and 40-2, can be randomly selected. The electrical bonding is performed using one or more intermediate contacts 41-1 which can without (necessary but possible) further electrical connection be placed at suitable points on the carrier 52.

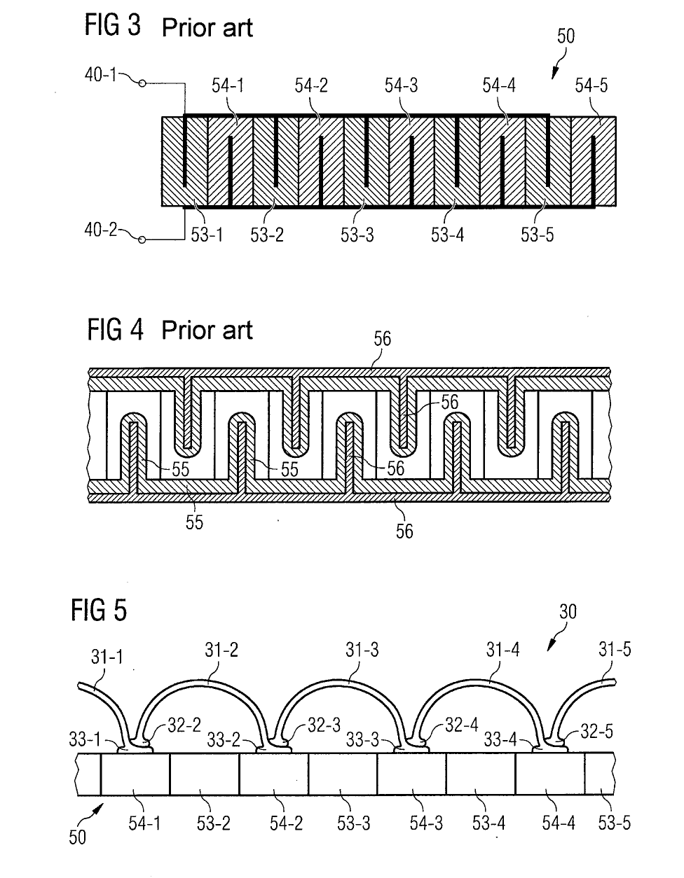

The procedure according to an embodiment can also be used for bonding e.g. a multilayer piezostack. This second exemplary embodiment of an electrical arrangement will be explained in detail with reference to FIGS. 3 to 5. FIGS. 3 and 4 show the basic structure of a multilayer piezostack from a plurality of solid-state actuators stacked on top of one another. These are labeled in the exemplary embodiment with the reference characters 53-i, 54-i, where i=1 to 5 (or in general n). The individual solid-state actuators are connected in parallel with one another. The elements 53-i are conventionally connected to one another via a soldered-wire connection to a connection contact 40-2. The elements or solid-state actuators 54-i are also connected via a soldered-wire connection to the connection contact 40-1. Wires 56 are connected to one another and to the respective connection contact in the manner shown in FIG. 4 via a solder paste. Of disadvantage in this procedure are soldering phenomena, by which are meant defective soldered connections due to materials which are not thermally adapted to one another. A further problem is the leaching of the solder surface (paste), caused by differing materials in the solder paste and the wire.

In contrast, FIG. 5 shows electrical bonding of a multilayer piezostack shown in FIG. 3 via a wire connection arrangement 30 according to an embodiment using chain bonding. As can clearly be seen from the drawing, the solid-state actuators 54-i are respectively connected to one another by a wire connection 31-i. For the sake of clarity, the wire chain connecting the solid-state actuators 53-i to one another electrically is not shown. The previously described principle of chain bonding is employed, wherein the first end of a wire connection is placed on the second end of a preceding wire connection. A thermocompression bonding method is preferably used here, as also described in conjunction with FIGS. 1 and 2.

An advantage of this connecting technology is that the thermal-load-bearing capacity of the bond connections is significantly higher than that of soldered connections. Furthermore, ageing of the connection contact, which occurs in a soldered connection, plays no role. The connecting method presented also enables the use of alternative surfaces, in particular of the contact points and further contact points, as a consequence of which cost advantages can be achieved.

1. An electrical arrangement comprising a first electrically conductive contact point and a second electrically conductive contact point, wherein
the first and the second contact point
are arranged at a distance from one another, and
are electrically connected to one another via a wire connection arrangements,
wherein the wire connection arrangement is formed by at least two wire connections which respectively have a first end and a second end, and the first end of one wire connection and the second end of a preceding wire connection are in direct contact with one another.

2. The arrangement according to claim 1, wherein
the first end of the wire connection is materially bonded to the second end of the adjacent, preceding wire connection.

3. The arrangement according to claim 1, wherein
the first end is superimposed on the second end.

4. The arrangement according to claim 3 wherein
the first end represents a nailhead, and the second end a wedge face, in particular a wedge, the first end being superimposed on the second end by means of a thermocompression bonding method.

5. The arrangement according to claim 1, wherein
the first and the second contact point are fashioned on a substrate arrangement and form electrical connection contacts of the arrangement, and the first or the second end of the wire connections that are connected to one another are arranged on a further contact point of the substrate arrangement and form an intermediate contact.

6. The arrangement according to claim 5, wherein
at least one substrate section of the substrate arrangement is electrically insulated in the area of the intermediate contact(s).

7. The arrangement according to claim 5, wherein
at least one substrate section of the substrate arrangement is electrically conductive in the area of the intermediate contact(s), whereby the further contact is conductively connected to the substrate arrangement.

8. The arrangement according to claim 5, wherein
the substrate arrangement is fashioned by a semiconductor element which is arranged on a carrier, whereby the first connection contact is fashioned on the semiconductor element and the second connection contact.

9. The arrangement according to claim 5, wherein
the substrate arrangement is formed by a number of elements, in particular solid-state actuators, stacked on top of one another, whereby the elements stacked on top of one another are connected in parallel via two wire connection chains which are formed respectively from a number of wire connections that are in direct contact with one another.

10. The arrangement according to claim 1, wherein
the wire connections and/or the contact points and/or the further contact point(s) have at least one surface made of gold.

11. A method for the production of an electrical arrangement comprising the steps:
a) providing a substrate arrangement comprising a first contact point, a second contact point and at least one further contact point;
b) producing a first connection, to the first contact point with a wire bonding device, wherein the first end of a first wire connection is connected, to the first contact point,
c) producing a second connection, to the further contact point with the wire bonding device, wherein the second end of the first wire connection is connected, to the further contact point, wherein the second end connected to the further contact point facing away from the further contact point;
d) producing a third connection, to the second end of the first wire connection with the wire bonding device, wherein the first end of a second wire connection is connected, to the wedge face of the first wire connection,
e) producing a fourth connection, to the second contact point with the wire bonding device, wherein the second end of the second wire connection is connected, to the second contact point.

12. The method according to claim 11, wherein
to produce a wire chain connection comprising more than two wire connections, steps c) and d) are repeated.

13. The method according to claim 11, wherein
the step of connecting one of the following contact partners is performed by microwelding:
the first end of the wire connection to the first contact point or to the second end of the preceding wire connection,
the second end of the wire connection to the further contact point or to the second contact point.

14. The method according to claim 11, wherein any of the first to fourth connection is a materially bonded connection.

15. An electrical arrangement comprising a first electrically conductive contact point and a second electrically conductive contact point arranged at a distance from one another, and electrically connected to one another by at least two wire connections, which respectively have a first end and a second end, wherein the first end of one wire connection and the second end of a preceding wire connection are in direct contact with one another.

16. The arrangement according to claim 15, wherein
the first end of the wire connection is materially bonded to the second end of the adjacent, preceding wire connection.

17. The arrangement according to claim 15, wherein
the first end is superimposed on the second end and wherein
the first end represents a nailhead, and the second end a wedge face, the first end being superimposed on the second end by means of a thermocompression bonding method.

18. The arrangement according to claim 15, wherein
the first and the second contact point are fashioned on a substrate arrangement and form electrical connection contacts of the arrangement, and the first or the second end of the wire connections that are connected to one another are arranged on a further contact point of the substrate arrangement and form an intermediate contact, wherein at least one substrate section of the substrate arrangement is electrically insulated in the area of the intermediate contact(s).

19. The arrangement according to claim 15, wherein
the first and the second contact point are fashioned on a substrate arrangement and form electrical connection contacts of the arrangement, and the first or the second end of the wire connections that are connected to one another are arranged on a further contact point of the substrate arrangement and form an intermediate contact, wherein at least one substrate section of the substrate arrangement is electrically conductive in the area of the intermediate contact(s), whereby the further contact is conductively connected to the substrate arrangement.

20. The arrangement according to claim 15, wherein
the wire connections and/or the contact points and/or the further contact point(s) have at least one surface made of gold.
